(19) United States
(12) Patent Application Publication
(10) Pub. No.: US 2013/0032828 A1
(43) Pub. Date: Feb. 7, 2013

(54) LED LIGHT STRIP MODULE STRUCTURE

(71) Applicant: Takeho HSU, Taipei City (TW)

(72) Inventor: Takeho HSU, Taipei City (TW)

(21) Appl. No.: 13/406,577

(22) Filed: Feb. 28, 2012

(30) Foreign Application Priority Data
Aug. 2, 2011 (TW) 100214228

(51) Int. Cl. H01L 33/44

(52) U.S. Cl. 257/88; 257/E33.061

(57) ABSTRACT

A LED light strip module structure includes a substrate and LED dies. The substrate has first and second surfaces. Accommodating cavities are formed on the first surface and extend toward the second surface. Each accommodating cavity has a bottom surface. Bonding metal layers are respectively attached to the bottom surfaces of the accommodating cavities. The LED die includes a crystal layer and a combination metal layer combined together. The LED dies are disposed in the accommodating cavities, respectively, so that the combination metal layer and the bonding metal layer form eutectic bonding. In addition, a diamond film layer may be disposed between the crystal layer and the combination metal layer, so that the LED die and the substrate can possess the stable and secure positioning effect and the thermoconductive speed and effect can be enhanced to lengthen the lifetime of the LED die through the diamond film layer.

### BACKGROUND OF THE INVENTION

1. Field of the Invention

The invention relates to the technical field of a light-emitting diode (LED) light strip module or a lamp body module, and more particularly to a LED light strip module structure using LEDs as light-emitting sources disposed on the same substrate.

2. Related Art

A light-emitting diode (LED) has the small size, the light weight, the long lifetime and the power-saving properties, so the LED has been widely used in various lamps.

The LED lamp usually includes multiple LED light strips or LED lamp boards serving as light sources. For example, the LED light strip mainly includes a strip-like (plate-like) metal substrate and LED dies disposed on the metal substrate, so that the LED light strip forms a module. Although the modularized LED light strip can provide the higher brightness, the great heat generated by the LED dies on the same substrate affects the lifetime of the LED light strip.

A known heat dissipating design for a LED includes a substrate, a silicon carrier, a LED and a glue. The substrate has a cavity and a circuit pattern. The silicon carrier, disposed in the cavity, has a first surface and a second surface combined together. In addition, at least the second surface is sputtered with an electroconductive material. The LED is bonded to the second surface of the silicon carrier using the eutectic or highly thermoconductive silver paste. A plurality of wires is electrically connected to the LED and the circuit pattern. The glue encapsulates the LED and the wires. In the prior art, the heat is firstly conducted to the silicon carrier, and then from the silicon carrier to the metal substrate.

### SUMMARY OF THE INVENTION

It is therefore an object of the invention to provide a LED light strip module structure capable of quickly conducting the heat so that the LED light strip has the good heat transfer effect and the lengthened lifetime.

According to the above-mentioned object and effect, the invention provides a light-emitting diode (LED) light strip module structure including a substrate and LED dies. Specifically, the substrate has a first surface and a second surface. Accommodating cavities are formed on the first surface and extend toward the second surface. Each accommodating cavity has a bottom surface. Bonding metal layers are respectively attached to the bottom surfaces of the accommodating cavities. The LED die includes a crystal layer and a combination metal layer combined together. The LED dies are disposed in the accommodating cavities, respectively, so that the combination metal layer and the bonding metal layer form eutectic bonding. In addition, a diamond film layer may be disposed between the crystal layer and the combination metal layer.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIGS. 1 and 2 are pictorial views showing the invention.

FIG. 3 is a schematic illustration showing a structure of the invention.

FIG. 4 is a schematic illustration showing another structure of the invention.

FIG. 5 is a schematic illustration showing another structure of the invention.

FIG. 6 is a schematic illustration showing a structure according to another embodiment of the invention.

FIG. 7 is a schematic illustration showing another structure according to another embodiment of the invention.

### DETAILED DESCRIPTION OF THE INVENTION

The present invention will be apparent from the following detailed description, which proceeds with reference to the accompanying drawings, wherein the same references relate to the same elements.

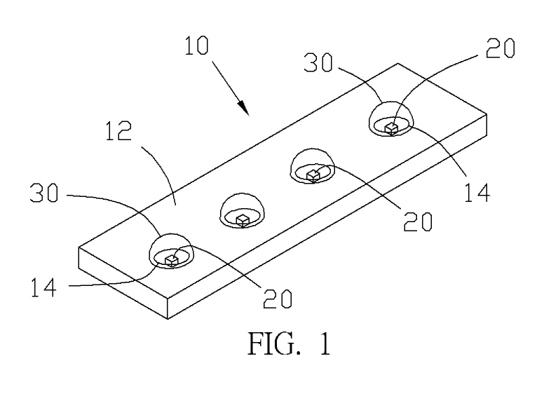

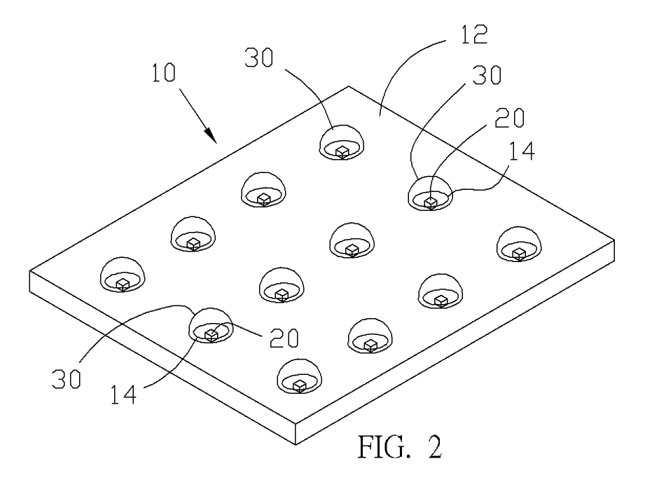

Referring to FIGS. 1 and 2, a light-emitting diode (LED) light strip module 10 may be a strip-like or plate-like module, and includes a substrate 12 and a plurality of LED dies 20. More specifically, the substrate 12 has a plurality of accommodating cavities 14, and the LED dies 20 are disposed in the accommodating cavities 14, respectively.

Furthermore, each LED die 20 is covered with a light-permeable glue 30. The glue 30 may contain the fluorescent powder excited by the light of the LED die 20.

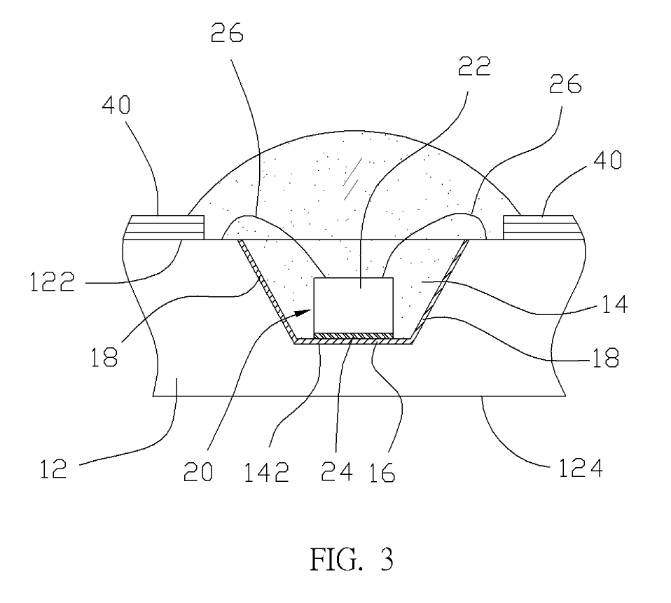

Referring to FIG. 3, the substrate 12 has a first surface 122 and a second surface 124. The accommodating cavity 14 is formed from the first surface 122 and extends toward the second surface 124. The bottom of the accommodating cavity 14 has a bottom surface 142.

The accommodating cavity 14 has an inclined lateral side surface. More particularly, a geometric shape of the accommodating cavity 14 from its opening to the bottom surface 142 is a frustum conical shape.

Next, a bonding metal layer 16 is disposed in each accommodating cavity 14. Specifically, the bonding metal layer 16 may be disposed on the bottom surface 142 of the accommodating cavity 14. Also, a heat transfer metal layer 18 is attached to the lateral side surface of the accommodating cavity 14.

The bonding metal layer 16 and the heat transfer metal layer 18 may be made of the same metal material or different metal materials, such as nano-gold or gold ions.

The LED die 20 has a crystal layer 22 and a combination metal layer 24 combined together. The crystal layer 22 is made of a semiconductor material by way of epitaxy, and can output light after being excited by the electric power. The combination metal layer 24 is disposed on one side of the crystal layer 22, may be made of nano-gold or gold ions, and may form the eutectic bonding together with the bonding metal layer 16 on the bottom surface 142.

In addition, the LED die 20 may be electrically connected to a multi-layer circuit 40 on the substrate 12 using suitable metal wires 26. The multi-layer circuit 40 is located on the first surface 122 of the substrate 12.

According to the above-mentioned structure, the LED die 20 is bonded to the bonding metal layer 16 by way of eutectic bonding using the combination metal layer 24 to achieve the effect of stabilizing the solid crystal. Next, the nano-gold or gold ions have the high heat conducting effect, so a portion of heat generated by the LED die 20 can be conducted from the bottom of the LED die 20 to the metal substrate 12, and the other portion of the heat, upon contacting with the heat transfer metal layer 18 on the lateral side wall of the accommodating cavity 14, can be quickly conducted to the metal substrate 12, and the quick thermoconductive effect can be achieved.

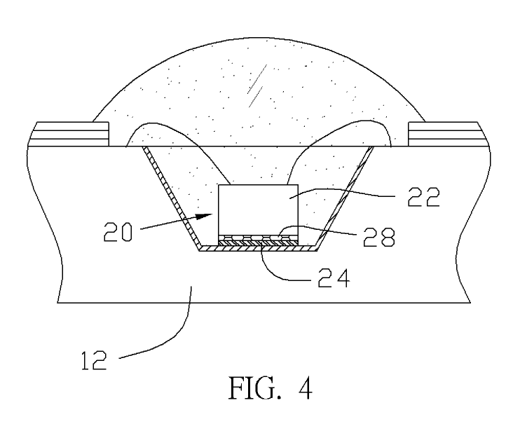

As shown in FIG. 4, the LED die 20 has a diamond film layer 28 disposed between the crystal layer 22 and the combination metal layer 24. The diamond film layer 28 is a smooth thin-layer structure and is not composed of diamond particles.

Because the diamond film layer 28 has the excellent and quick thermoconductive effect and the diamond film layer 28 can form the good sticking effects with the crystal layer 22 and the combination metal layer 24, the heat generated by the LED die 20 can be quickly absorbed by the diamond film layer 28 and conducted to the substrate 12, so that the temperature of the LED die 20 can be decreased.

Furthermore, the diamond film layer 28 has the smooth surface rather than the particle-like or concave-convex surface, so the thickness of the diamond film layer 28 can be decreased, and the crystal layer 22 can be easily formed on the diamond film layer 28.

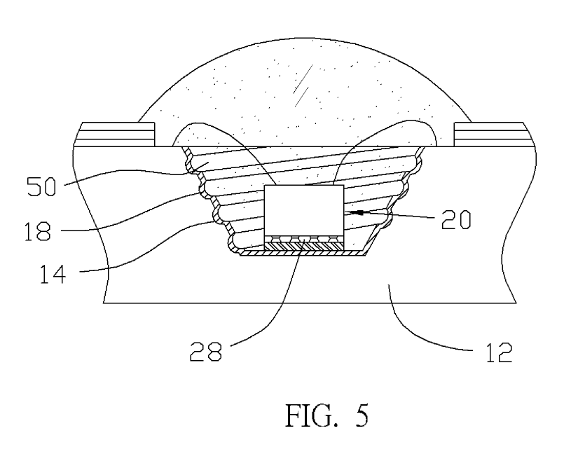

As shown in FIG. 5 according to another embodiment of the invention, the lateral side wall of the accommodating cavity 14 is formed with a threaded structure 50, and the heat transfer metal layer 18 is attached to the threaded structure 50. Using the threaded structure 50 in conjunction with the conical shape of the accommodating cavity 14, the heat outputted from the LED die 20 can generate the spiral flow and contact with the heat transfer metal layer 18 quickly and at the high collision possibility, so that the heat is conducted to the substrate 12 through the heat transfer metal layer 18.

According to the design of the invention, the LED die 20 and the substrate 12 can possess the stable and secure positioning effect and enhance the thermoconductive speed and effect through the diamond film layer 28. In addition, the mutual collocation between the heat transfer metal layer 18, the conical accommodating cavity 14 and/or the threaded structure 50 can further enhance the heat transfer effect and thus lengthen the lifetime of the LED die 20.

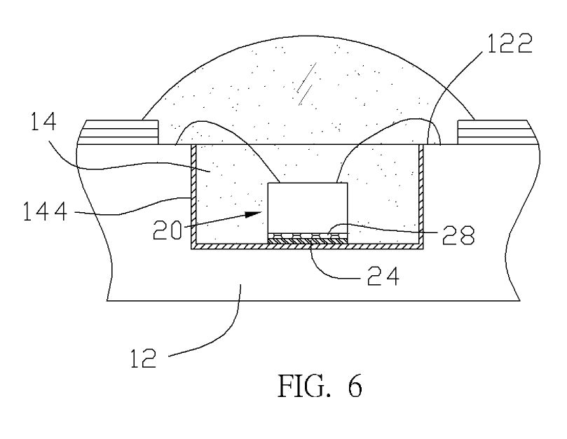

As shown in FIG. 6, a lateral side wall 144 of the accommodating cavity 14 of the invention may be formed to be perpendicular to the first surface 122 of the substrate 12 so that the accommodating cavity 14 has a rectangular opening.

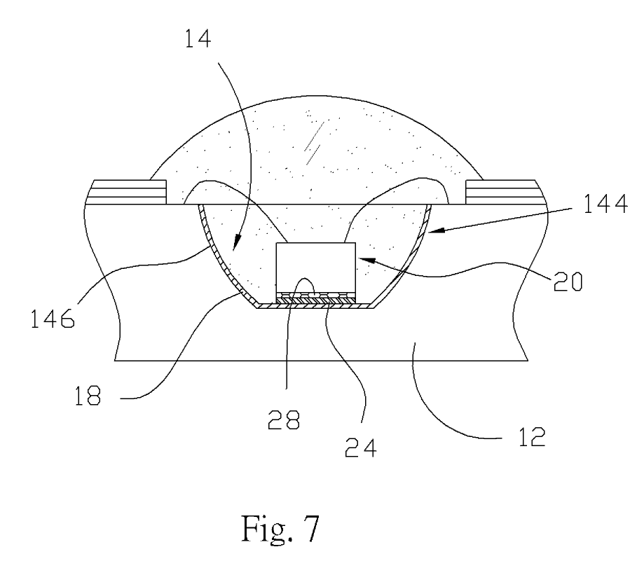

As shown in FIG. 7, the lateral side wall 144 of the accommodating cavity 14 may be formed with an arced concave structure 146, on which the heat transfer metal layer 18 is formed. The heat generated by the LED die 20 contacts with the lateral side wall 144 having the arced concave structure 146, and is then quickly conducted to the substrate 12 in a thermal spin manner.

The form of the LED die 20 having the diamond film layer 28 fixed to the accommodating cavity 14 in conjunction with the combination metal layer 24 is equivalent to that of the above-mentioned embodiment, and the structure thereof can possess the high efficiency heat transfer effect.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. A light-emitting diode (LED) light strip module structure, comprising:
a substrate having a first surface and a second surface;
a plurality of accommodating cavities formed on the first surface and extending toward the second surface, each of the accommodating cavities having a bottom surface;
a plurality of bonding metal layers attached to the bottom surfaces of the accommodating cavities, respectively; and
a plurality of LED dies each comprising a crystal layer and a combination metal layer combined together, wherein the LED dies are disposed in the accommodating cavities, respectively, so that the combination metal layer and the bonding metal layer form eutectic bonding.

2. The module structure according to claim 1, wherein the crystal layer has a diamond film layer bonded to the combination metal layer.

3. The module structure according to claim 1, wherein the bonding metal layer and the combination metal layer are made of nano-gold or gold ions.

4. The module structure according to claim 1, wherein a lateral side wall of the accommodating cavity has an inclined shape, so that the accommodating cavity forms a frustum conical shape.

5. The module structure according to claim 1, wherein a lateral side wall of the accommodating cavity is perpendicular to the first surface, so that the accommodating cavity forms a rectangular opening structure.

6. The module structure according to claim 1, wherein a lateral side wall of the accommodating cavity has a threaded structure.

7. The module structure according to claim 1, wherein a lateral side wall of the accommodating cavity is formed with an arced concave structure.

8. The module structure according to claim 1, wherein a heat transfer metal layer is attached to a lateral side surface of the accommodating cavity.

9. The module structure according to claim 1, further comprising a glue, which has fluorescent powder, is filled into each of the accommodating cavities and corresponds to the LED die.

10. The module structure according to claim 1, further comprising a multi-layer circuit disposed on the first surface of the substrate.
